(19) United States
(12) Patent Application Publication
(10) Pub. No.: US 2012/0237859 A1
(43) Pub. Date: Sep. 20, 2012

(54) METHOD OF APPROXIMATING VALUE OF CRITICAL DIMENSION OF PATTERN FORMED BY PHOTOLITHOGRAPHY AND METHOD OF FABRICATING PHOTOMASK INCLUDING OPC BASED ON APPROXIMATED VALUE OF A CD OF A PATTERN

(75) Inventors: Seung-hune Yang, Seoul (KR); Seong-ho Moon, Yongin-si (KR); Sang-hun Kim, Yongin-si (KR); Ju-yun Park, Suwon-si (KR)

(73) Assignee: SAMSUNG ELECTRONICS CO., LTD., SUWON-SI (KR)

(21) Appl. No.: 13/343,425

(22) Filed: Jan. 4, 2012

(30) Foreign Application Priority Data
Mar. 15, 2011 (KR) 10-2011-0022883

(51) Int. Cl. G03F 1/36

(52) U.S. Cl. 430/5

(57) ABSTRACT

A method of fabricating a photomask includes OPC of a mask pattern based on an approximated (i.e., a predicted) critical dimension (CD) of a film pattern formed using the photomask. First, a photomask is provided, a photosensitive film pattern is formed by a lithographic process using the photomask, a CD of the photosensitive film pattern is determined using a scanning electron microscope (SEM), and a value of the CD of the photosensitive film pattern, at a point in time before the film pattern has been shrunk by the SEM, is approximated by measuring the CD using a reference microscope (e.g., an AFM) and the SEM or just by using the SEM in several sequences.

### CROSS-REFERENCE TO RELATED APPLICATIONS

This application claims the benefit of Korean Patent Application No. 10-2011-0022883, filed on Mar. 15, 2011, in the Korean Intellectual Property Office, the disclosure of which is incorporated herein by reference in its entirety.

### BACKGROUND

The inventive concept relates to the process of photolithography used in the manufacturing of semiconductor devices and the like. More specifically, the inventive concept relates to the fabricating of photomasks used in photolithography and, in particular, to an optical proximity correction (OPC) method using Critical Dimension-Scanning Electron Microscopy (CD-SEM).

Various patterns, including circuit patterns of semiconductor devices and the like, are formed on a wafer (e.g., a silicon wafer) using photolithography. To this end, the photolithography process employs a photomask (also referred to as a reticle). The photomask bears a pattern corresponding, for example, to the desired circuit pattern to be transcribed onto a target layer on the wafer. In the photolithography process, the target layer is coated with a photosensitive film (referred to as photoresist or simply “resist”), and the resist is exposed to light directed onto the resist via the photomask resulting in a transfer of an image of the photomask pattern to the resist. Then the exposed or non-exposed portion of the resist is developed thereby patterning the resist. Finally, the underlying target layer is etched using the resist pattern (PR pattern) as an etching mask.

However, a critical dimension (CD) of the circuit pattern formed may have irregularities due to process errors including optical effects such as diffraction in the projection of light onto the resist and/or defects inherent in the photolithographic equipment. Examples of these irregularities in the CD include line widths that are narrower or wider than those desired. The magnitude of the effect of these errors on product yield has increased as the design rule of semiconductors has decreased. Thus, various techniques have been developed to optimize photolithographic processes, especially in connection with those processes used to form patterns whose critical dimensions, such as line widths, are very fine, i.e., are significantly smaller than the wavelength of the exposure light used.

Optical proximity correction (OPC) is a photolithography enhancement technique which has been developed to compensate for image projection errors in the fabrication of semiconductor devices having small design rules. OPC corrects the image projection errors by correcting and the pattern of the photomask and thereby transforming the photomask. The correction may be rule driven (known as rule based OPC) using tables of correction data based on width and spacing between features of the photomask pattern, or may be model driven (known as model based OPC) using models to simulate the final photomask pattern.

Essential to the generation of correction data or models used in OPC is the acquisition of data accurately representative the value of the CD of a circuit pattern produced using the photomask, e.g., the accurate measuring of the CD. To this end, a scanning electron microscope (SEM) has been used. However, there remains a need for more accurate Critical Dimension-Scanning Electron Microscopy (CD-SEM) tools to measure, characterize and quantify the CDs.

### SUMMARY

According to one aspect of the inventive concept, there is provided a method of fabricating a photomask, comprising: providing a photomask having a mask pattern, patterning a film on a substrate using the photomask in a lithographic process to thereby form a film pattern bearing an image of at least part of the mask pattern, measuring a critical dimension (CD) of the film pattern including by exposing the film pattern to a scanning electron microscope (SEM) and extracting a value of the CD from an image of the film pattern produced by the SEM, using the measured CD in approximating (predicting) the value of the CD of the film pattern possessed by the film pattern at a point in time before the film pattern was imaged by the SEM, and performing an optical proximity effect correction (OPC) of the photomask using the approximated value of the CD. In OPC, an original mask pattern of the photomask subjected to the OPC is altered.

According to another aspect of the inventive concept, there is provided a method of fabricating a photomask, comprising: providing a photomask having a mask pattern, patterning a film on a substrate using the photomask in a lithographic process to thereby form a film pattern bearing an image of at least one feature of the mask pattern, determining at least one value of the critical dimension (CD) of the film by scanning the film pattern with an electron beam of a scanning electron microscope (SEM), using the at least one value of the CD determined using the SEM in approximating the value of the CD of the film pattern possessed by the film pattern at a point in time before the film pattern was irradiated by the electron beam of the SEM, whereby the approximated value of the CD of the film pattern is not influenced by any shrinkage of the film pattern caused by the electron beam, factoring the approximated value of the CD of the film pattern into an optical proximity effect correction (OPC) model, and altering a mask pattern of a photomask using the optical proximity effect correction (OPC) model into which the approximated value of the CD of the film pattern has been factored.

According to still another aspect of the inventive concept, there is provided a method for use in fabricating a photomask, comprising: providing a photomask having a mask pattern, forming a photosensitive film pattern using the photomask and measuring a CD of the photosensitive film pattern at least one time using a scanning electron microscope (SEM), and predicting a value of the CD of the photosensitive film pattern, at a point in time before the CD of the film pattern has been altered by the SEM, using at least a value or values of the CD measured using the SEM.

### BRIEF DESCRIPTION OF THE DRAWINGS

These and other aspects of the inventive concept and advantages thereof will be more clearly understood from the following detailed description made in conjunction with the accompanying drawings in which:

FIG. 1 is a flowchart of a method of approximating a critical dimension (CD) of a photosensitive film pattern, according to the inventive concept;

FIG. 2 is a schematic diagram of a scanning electron microscope (SEM) used in the method of FIG. 1 for measuring a CD of a photosensitive film pattern;

FIG. 3 is a diagram of image frames of a SEM as the CD of a pattern is being measured by the SEM, and illustrates the shrinkage of the photosensitive film pattern as the result of the use of the SEM;

FIG. 4 is a graph of the reduction in the CD of a photosensitive film pattern as the CD of the pattern is being measured by the SEM;

FIG. 5 is a graph of the reductions in the CDs of various photosensitive film bar patterns as images of the patterns are being obtained using the SEM;

FIG. 6 is a flowchart of one embodiment of a method of approximating a CD of a photosensitive film pattern, according to the inventive concept;

FIG. 7 is a graph of measurements obtained using the method of FIG. 6, and illustrates how the measurements may be used for obtaining a metrology model that can be used to approximate the CD;

FIG. 8 is a flowchart of another embodiment of a method of approximating a CD of a photosensitive film pattern, according to the inventive concept;

FIGS. 9 through 11 are conceptual diagrams illustrating examples of techniques of measuring a CD of a photosensitive film pattern using a SEM, for use in an example of the method of FIG. 8 in which the value of a CD of a line and space pattern is approximated;

FIGS. 12A through 12C are graphs of examples of CD data acquired using a technique illustrated in FIGS. 9-11, for use in the example of the method of FIG. 8 in which the value of a CD of a line and space pattern is approximated;

FIG. 13 is a graph including values obtained from the graphs FIGS. 12A through 12C, and illustrates the creation of a SEM bias model for use in a method according to the inventive concept; and

FIG. 14 is a flowchart of a method of fabricating a photomask according to the inventive concept.

### DETAILED DESCRIPTION OF THE EMBODIMENTS

Various embodiments and examples of embodiments of the inventive concept will be described more fully hereinafter with reference to the accompanying drawings. In the drawings, the sizes and relative sizes and shapes of features may be exaggerated for clarity.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. Also, the term photomask as used herein may refer to a reticle.

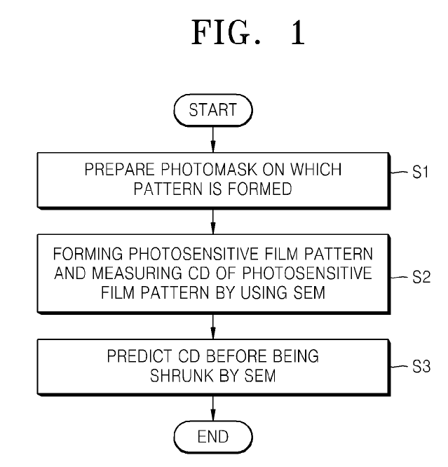

A method of approximating a CD of a photosensitive film pattern, according to the inventive concept, will now be described generally with respect to the flowchart of FIG. 1.

The method includes providing a photomask on which a pattern has been formed (S1), forming a photosensitive film pattern on a substrate (e.g., a wafer such as a silicon wafer) using the photomask, and measuring a CD of the photosensitive film pattern (“PR pattern” hereinafter) using a scanning electron microscope (SEM) (S2), and approximating the CD of photosensitive film pattern using the CD measured by using the SEM (S3).

With respect to step S1, the photomask pattern may consist of a single or a plurality of features. In the case in which the photomask pattern has a plurality of features, the features may be periodic, e.g., the pattern may be a line and space pattern or a hole pattern. However, the inventive concept is not so limited and may be applied to a photomask having an aperiodic pattern of features. Step S2 may comprise basic photolithographic and etching processes, in which the photosensitive film is exposed to light directed through the photomask and is then developed. When the CD is measured using the SEM in step S3, the electron beam of the SEM causes the PR pattern to shrink and hence the CD may also be reduced.

According to the inventive concept, in S3, the value of the CD at a point in time before the PR pattern began to shrink is approximated using the CD measured in operation S2. The approximated value of the CD may then be used for optical proximity correction (OPC). Accordingly, the resulting OPC model may be extremely effective, and thus, the pattern of a photomask may be corrected more precisely. Accordingly, a highly uniform minute pattern can be produced using such a corrected photomask.

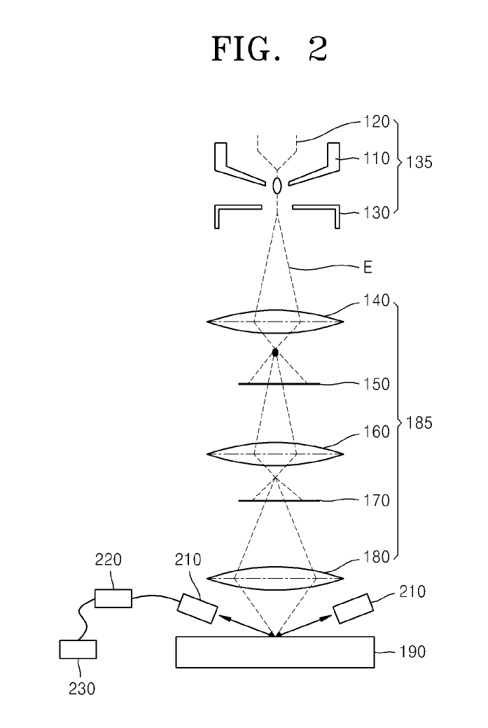

A SEM for use in measuring the CD of a photosensitive film pattern in a method according to the inventive concept will now be described in detail with reference to FIG. 2.

Referring to FIG. 2, the SEM includes a filament unit 135 for generating electrons, an electron lens unit 185 for focusing and accelerating the electrons, and a detector 210 for gathering and detecting secondary electrons, or the like. The filament unit 135 includes an electron gun cylinder 110, a filament 120 operating as a cathode, and an acceleration electrode 130 operating as an anode. The electron lens unit 185 includes a first focus lens 140, a first diaphragm 150, a second focus lens 160, a second diaphragm 170, and an object lens 180. When a voltage is applied to the filament 120, electrons are emitted from the filament 120 and a series of bunches of electron are accelerated toward a semiconductor device 190 by an electric potential applied to the acceleration electrode 130. The electron bunches are focused by the first and second focus lenses 140 and 160 onto the first and second diaphragms 150 and 170, respectively. The electron beam E which emerges from the electron lens unit 185 is focused on the semiconductor device 190 by the object lens 180. The electron beam E incident on the semiconductor device 190 and atoms and electrons that make up the layer on the semiconductor device 190 irradiated by the beam interact with each other to emit particles such as secondary electrons, back-scattering electrons, and the like. The particles are gathered and converted into a digital signal by the detector 210. The digital signal is reinterpreted by an arithmetic unit 220 using a suitable algorithm, and is then stored or output as an image on a screen 230 of a display device.

Generally, the image output on the screen 230 of the display device by the SEM is obtained from a series of image frames (frame 1 through frame k) produced in chronological order. More specifically, groups of particles emitted by continuously irradiating a certain point on the semiconductor device 190 with the electron beam E are sequentially detected and processed, thereby providing a series of images (image frame 1 through image frame k) of the semiconductor device 190 in chronological order, and values representative of these images are integrated to produce one image output on the screen 230 of the display device.

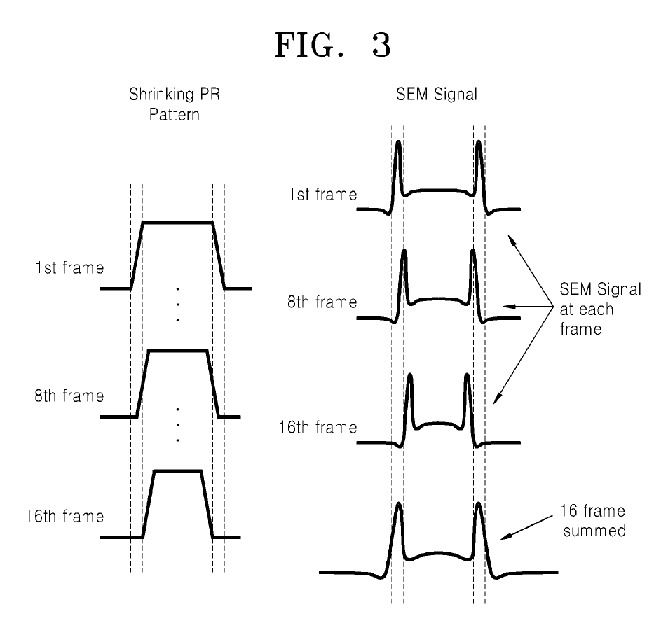

FIG. 3 is a diagram illustrating the imaging of (a feature of) a photosensitive film pattern using a SEM of the type described above. The left half of the diagram shows profiles of the photosensitive film pattern and the right half of the diagram shows the corresponding SEM signals produced and a result of integrating the signals, with respect to 16 image frames.

As shown by the image frames in FIG. 3, which are produced in chronological order, the photosensitive film pattern gradually shrinks as the electron beam E emitted from the SEM remains incident on the photosensitive film pattern.

Generally, as is also shown in FIG. 3, the image of a pattern is formed by integrating the image frames produced by irradiating the pattern with the electron beam produced by the SEM for a certain period of time. The photomask used to produce the pattern is then finalized/corrected by performing an OPC based on the CD of the image output by the SEM. However, as described above, the photosensitive film pattern shrinks as the photosensitive film pattern is being imaged by the SEM and hence, the CD of the pattern changes. Thus, the model derived by the OPC technique may be inaccurate.

According to an aspect of the inventive concept, OPC of a photomask used to produce a photosensitive film pattern is performed using a value of the CD of the film pattern derived from the output of a SEM image of the film pattern but based on an approximation of a value of the CD before the CD is measured using the SEM, i.e., before the photosensitive film pattern is shrunk by the electron beam of the SEM. Thus, a highly accurate OPC model may be produced, i.e., the error rate of OPC may be decreased. Accordingly, a photomask that produces a better film pattern, i.e., a highly uniform minute pattern, may be provided. Note, the term CD as used herein may not only refer to the width of a line of a line and space pattern, but may refer to any dimension of the film pattern to be checked such as the pitch of the lines of a line and space pattern. That is, for purposes of this specification, the CD is not necessarily the smallest dimension of the pattern produced using the photomask.

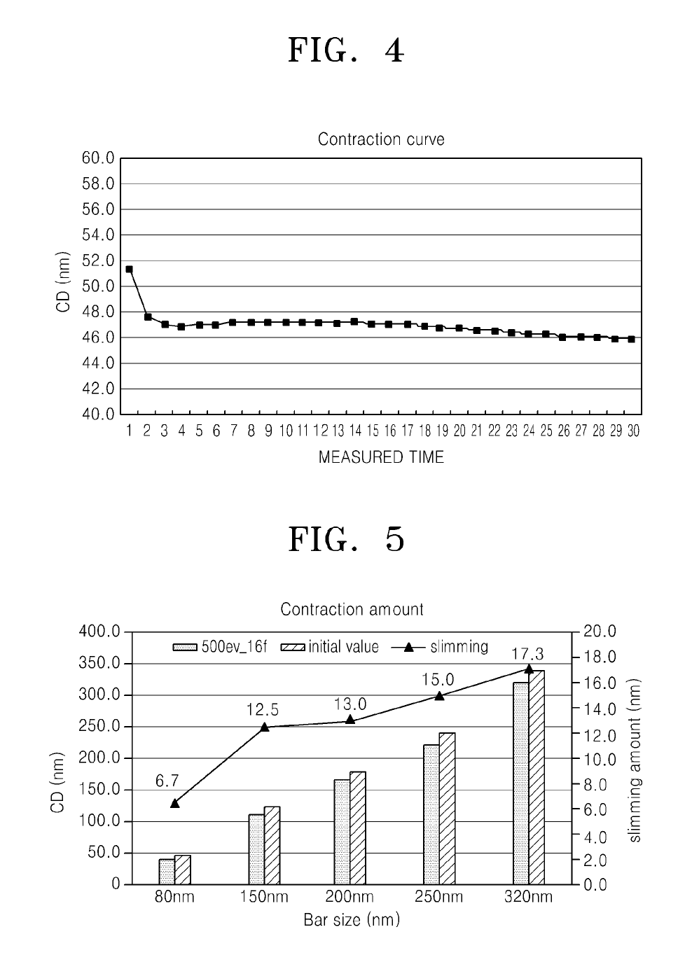

FIG. 4 is a graph of an example of values of a CD of a photosensitive film pattern over time as the CD is being measured by a SEM, illustrating a reduction in the CD of the photosensitive film pattern.

FIG. 5 is a graph of values in the reduction of CDs of various photosensitive film bar patterns as the result of the imaging of the patterns using an SEM. In these examples, each of the photosensitive film bar patterns had a pitch of 400 nm. FIG. 5 shows that the greater the size of the photosensitive film bar pattern, the greater is the shrinkage of the CD of the pattern.

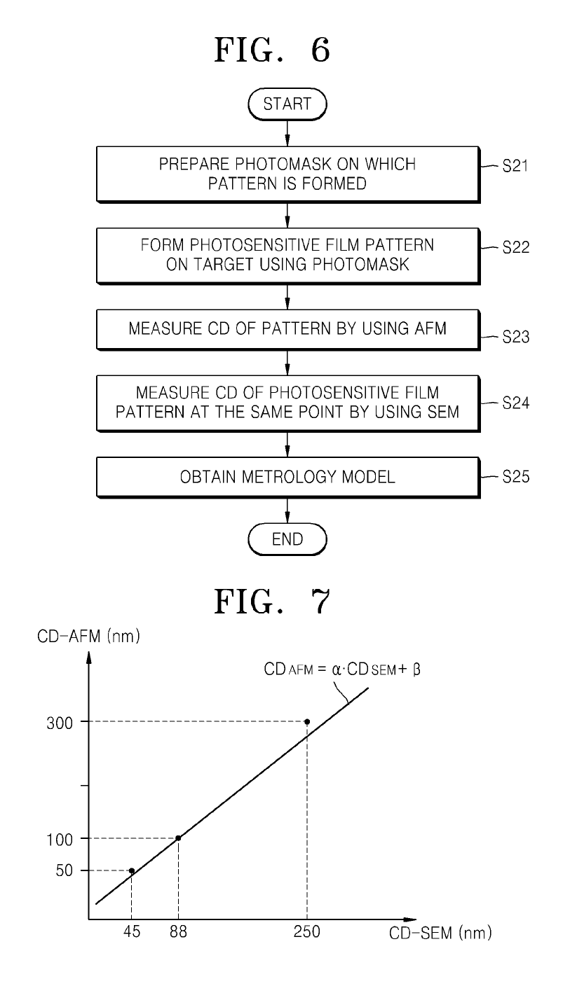

One embodiment of a method of approximating a CD of a photosensitive film pattern, according to the inventive concept, will now be described in detail with reference to the flowchart of FIG. 6.

A photomask having a photomask pattern provided (S21), and then a photosensitive film pattern is formed on a target (wafer on which the photosensitive film has been formed, for example) using the photomask (S22). The pattern may be periodic or aperiodic.

Then, a CD of the pattern is measured, at a certain point on the wafer, using an AFM (Atomic Force Microscope) (S23). In this embodiment, the AFM is used to generate reference data. Alternatively, the CD may be measured by scanning probe microscopy (SMP), e.g., by a scanning tunneling microscope (STM) or a scanning capacitance microscope (SCM).

Next, the CD of the photosensitive film pattern is measured using a SEM (S24). To this end, the SEM is used to produce an image of the photosensitive film pattern at the same point probed by the AFM. Also, as an example, the measuring of the CD of the photosensitive film pattern using the SEM may comprise generating 16 image frames and integrating values representative of the 16 images frames.

Then, the difference between the CD measured using the AFM and the CD measured using the SEM is used to derive a metrology model (S25).

FIG. 7 is a graph showing an example of how such a metrology model may be obtained (S25) from data output by the AFM and SEM. In this example, several different photoresist line and space patterns are formed using the photomask (i.e., step S22 is performed several times varying the lithography process so that the line and space patterns formed have different CDs).

Referring to the graph of FIG. 7, in a first iteration of steps S23 and S24, the CD of a photosensitive film pattern measured using the AFM was 50 nm and the CD of the photosensitive film pattern subsequently measured using the SEM was 45 nm. In a second iteration of steps S23 and S24, the CD of another photosensitive film pattern measured using the AFM was 100 nm and the CD of the same photosensitive film pattern subsequently measured using the SEM was 88 nm. In a third iteration of steps S23 and S24, the CD of still another photosensitive film pattern measured using the AFM was 300 nm and the CD of that photosensitive film pattern subsequently measured using the SEM was 250 nm.

Then, a metrology model, e.g., CD_{AFM}=α·CDₛₑₘ+β, is obtained using the values of the CDs of the photosensitive film patterns measured using the AFM and the SEM. In this model, CD_{AFM} is an approximation of a CD of a photosensitive film pattern at a point in time before the pattern begins to shrink due to its being irradiated by the electron beam of the SEM, a denotes a slope of the linear function, β denotes a y-intercept (offset) of the function, and CDₛₑₘ denotes the CD of the photosensitive film pattern measured using the SEM. Note, although in this example the metrology model is derived as a linear function of CD_{AFM} and CDₛₑₘ, the inventive concept is not so limited. Rather, the metrology model derived from the data output by the AFM and SEM may be a quadratic function of CD_{AFM} and CDₛₑₘ. In any case, the metrology model can then be used in a subsequent OPC process. More specifically, a photomask is used to form a line a space pattern, a CD of the line and space pattern is measured using the SEM, the value of the CD obtained using the SEM is used in the model to obtain a CD value of CD_{AFM}, and the photomask is then finalized/corrected (i.e., the pattern thereof is altered) based on the value of CD_{AFM} obtained from the metrology model. In this way, the OPC of a series of photomasks can be performed without resorting back to the use of the AFM, the operation of which is relatively time consuming.

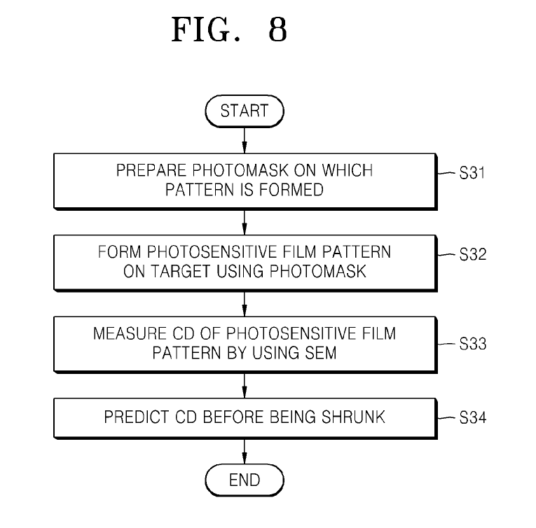

One embodiment of a method of approximating a CD of a photosensitive film pattern, according to the inventive concept, will now be described in detail with reference to the flowchart of FIG. 8. This embodiment does not use an AFM to produce reference data and thus, is more advantageous in terms of time savings or in cases in which an AFM is likely to produce unacceptable errors.

Referring to FIG. 8, a photomask having a photomask pattern provided (S31), and then a photosensitive film pattern is formed on a target (wafer on which the photosensitive film has been formed, for example) using the photomask (S32). The pattern may be periodic or aperiodic.

Then, a CD of the photosensitive film pattern is measured, at a certain point on the wafer, using a SEM (S33).

Next, a value of the CD of the photosensitive film pattern before the pattern has been shrunk by the electron beam of the SEM is approximated from data only collected using the SEM (S34).

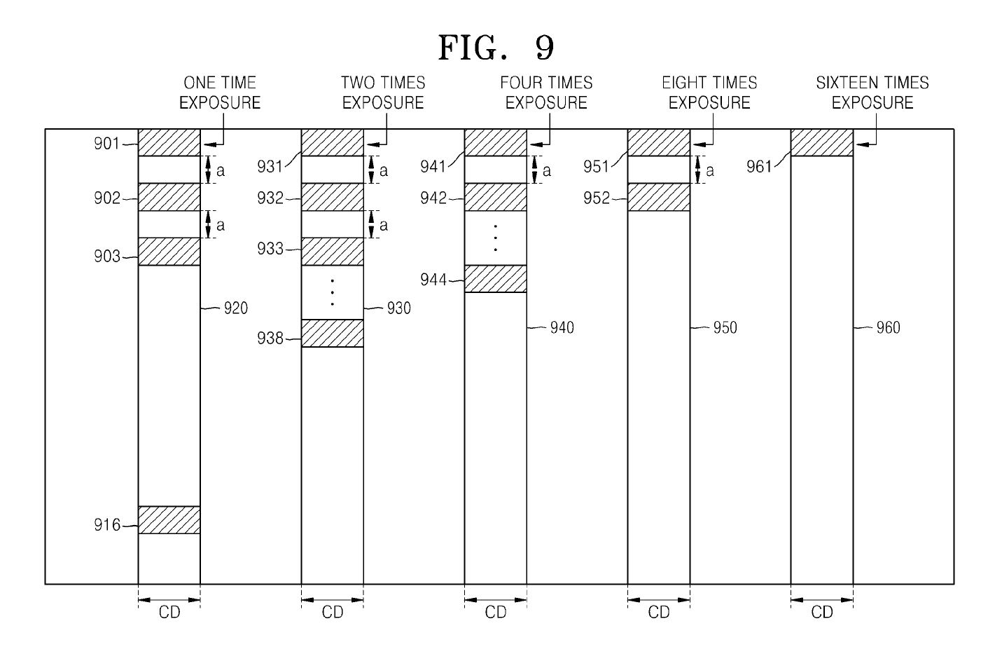

Examples of the step (S33) of measuring the CD of the photosensitive film pattern using the SEM to acquire data used in predicting the value of the CD at the point in time before the SEM was used, i.e., before the photosensitive film pattern was irradiated by the electron bean of the SEM, will now be described with respect to FIGS. 9 through 11. In each of these examples, the pattern whose CD is approximated is a line and space pattern.

Referring to FIG. 9, a line and space photosensitive film pattern including first through fifth lines 920 through 960 is formed on a semiconductor substrate using a photomask having a mask pattern designed to provide CD uniformity. That is, the lines of the line and space pattern produced using the photomask 920 through 960 are to have the same widths.

Then, the first pattern 920 is selected from the line and space photosensitive film pattern.

Next, a SEM image of the first line 920 is captured by exposing the first line 920 to the SEM a first number of times, for example one time, along the length of the first line 920, and a CD of the first pattern 920 is determined from the imaging of the first line 920 by the SEM. The SEM image is obtained by integrating a plurality of image frames. In this example, 16 image frames are integrated to obtain the SEM image of the first line. More specifically, the CD of the first line 920 is determined, in this example, as follows.

First, a first image frame is obtained by irradiating a first point 901 along the first line 920 with the electron beam of the SEM. Then, a second image frame is obtained by irradiating a second point 902 along the first line 920 with the electron beam of the SEM, wherein the second point 902 is spaced from the first point 901 by a predetermined distance a along the length of the first line 920. Then this process is repeated to obtain third through sixteenth image frames by sequentially irradiating points 903 . . . 916 spaced from each other by the predetermined distance a along the length of the first line 920.

Then, (values of signals representative of) the first through sixteenth image frames are integrated to form the SEM image of the first line 920, and a value of the CD of the first pattern 920 is extracted from the SEM image of the first line 920 so produced.

Next, the second line 930 is selected from the line and space photosensitive film pattern, and a SEM image of the second line 930 is captured by exposing the second line 930 to the SEM a second number of times different from the first number, for example, two times, along the length the second line 930. In addition, a CD of the second line 930 is determined from the imaging of the second line 930 by the SEM two times. More specifically, the CD of the second line 930 is determined, in this example, as follows.

First, first and second image frames are produced by exposing a first point 931 of the second line 930 to the SEM twice, i.e., by irradiating the first point 931 of the second line 930 with the electron beam of the SEM in two discrete SEM imaging operations. Next, third and fourth image frames are produced by exposing a second point 932 of the second line 930 to the SEM twice, wherein the second point 932 is spaced apart from the first point 931 by the predetermined distance a along the length direction of the second line 930.

Then, this process is repeated, to produce two image frames for each of third through eighth points 933 . . . 938 spaced apart from one another by the predetermined distance a along the length of the second line 930. Sixteen image frames are thus produced in total for the second line 930.

Values of signals representative of these sixteen image frames are integrated to form a SEM image of the second line 930, and a value of the CD of the second line 930 is extracted from the SEM image of the second line 930.

Then, the third line 940 is selected from the line and space photosensitive film pattern, and a SEM image of the third line 940 is captured by exposing the third line 940 to the SEM a second number of times different from the first and second number of time, for example, four times, along the length the second line 930. In addition, a CD of the third line 940 is determined from the imaging of the third line 940 by the SEM four times. More specifically, the CD of the third line 940 is determined, in this example, as follows.

A first point 941 of the third line 940 is exposed to the SEM four times to produce first, second, third and fourth image frames. That is, the first point 941 of the third line 940 is irradiated with the electron beam of the SEM in four discrete SEM imaging operations. Next, fifth through eighth image frames are produced by exposing a second point 942 of the third line 940 to the SEM four times, wherein the second point 942 is spaced apart from the first point 941 by the predetermined distance a along the length direction of the third line 940.

Then, this process is repeated, to produce four image frames for each of a third point and a fourth point 944 spaced apart from one another by the predetermined distance a along the length of the third line 940. Sixteen image frames are thus produced in total for the third line 940, as well.

Values of signals representative of these sixteen image frames are integrated to form a SEM image of the third line 940, and a value of the CD of the third line 940 is extracted (measured) from the SEM image of the third line 940.

Then, the fourth line 950 is selected, and a SEM image of the fourth line 950 is captured by exposing the third line 940 to the SEM a fourth number of times different from the first, second and third number of times, for example, eight times, along the length the fourth line 950. In addition, a CD of the fourth line 950 is determined from the imaging of the fourth line 950 by the SEM eight times. More specifically, the CD of the fourth line 950 is determined, in this example, as follows.

A first point 951 of the fourth line 950 is exposed to the SEM eight times to produce first, second, third, fourth, fifth, sixth, seventh and eighth image frames. That is, the first point 951 of the fourth line 950 is irradiated with the electron beam of the SEM in eight discrete SEM imaging operations. Next, ninth through sixteenth image frames are produced by exposing a second point 952 of the fourth line 950 to the SEM eight times, wherein the second point 952 is spaced apart from the first point 951 by the predetermined distance a along the length direction of the fourth line 950.

Values of signals representative of these sixteen image frames are integrated to form a SEM image of the fourth line 950, and a value of the CD of the fourth line 950 is extracted from the SEM image of the fourth line 950.

Then, the fifth line 960 is selected and a SEM image of the fifth line 960 is captured by exposing the fifth line 960 to the SEM a fifth number of times different from the first, second, third and fourth number of times, for example, sixteen times. In addition, a CD of the fifth line 960 is determined from the imaging of the fifth line 960 by the SEM sixteen times.

That is, in this example, a first point 961 of the fifth line 960 is exposed to the SEM sixteen times to produce sixteen image frames. That is, the first point 961 of the fifth line 960 is irradiated with the electron beam of the SEM in sixteen discrete SEM imaging operations.

Values of signals representative of these sixteen image frames are integrated to form a SEM image of the fifth line 960, and a value of the CD of the fifth line 960 is extracted from the SEM image of the fifth line 960.

In the example described above, the image output by the SEM of each of five lines is obtained by integrating 16 image frames produced in chronological order. However, this technique is not limited to any certain number of lines of a line and space pattern or to the number of image frames produced for each line of the pattern. In this technique, the total number of image frames to produced for each line may be broken down into its factors, and each of a number of lines corresponding to the number of factors are sampled, with each line being imaged at a number of points corresponding to a respective one of the factors. In addition, for each line, the line is imaged at a number of points corresponding to one of a respective pair of the factors and each point is exposed to the SEM a number of times corresponding to the other of the respective pair of factors. In the above example, the number sixteen (i.e., the number of image frames to be produced by the SEM for each line) has five factors (1, 2, 4, 8 and 16) and so, five lines of a line and space pattern are selected, and 1, 2, 4, 8 and 16 points along the selected lines, respectively, are imaged. And, for each line, the line is imaged at a respective number of points (1, 2, 4, 8 or 16) corresponding to one of a respective pair of the factors of the number sixteen, and each point on the line is exposed to the SEM a number of times (16, 2, 4, 8 or 1) corresponding to the other of the respective pair of factors.

Thus, this technique may be employed in the case in which it is desired to use only 12 image frames for each line. In this example, the number 12 has six factors (1, 2, 3, 4, 6 and 12) and thus six lines of a line and space pattern produced using the photomask are selected sequentially. Therefore, in this example, the CD of a first line of the line and space pattern may be measured by integrating 12 image frames each produced by exposing the first line to the SEM once at each of 12 respective points spaced along the length of the first line; the CD of a second line of the line and space pattern may be measured by integrating 12 image frames produced by exposing the second line to the SEM two times at each of 6 respective points spaced along the length of the second line; a CD of a third line of the line and space pattern may be measured by integrating 12 image frames produced by exposing the third line to the SEM three times at each of 4 respective points spaced along the length of the third line; the CD of a fourth line of the line and space pattern may be measured by integrating 12 image frames produced by exposing the fourth line to the SEM four times at each of 3 respective points along the length of the fourth pattern, the CD of a fifth line of the line and space pattern may be measured by integrating 12 image frames produced by exposing the fifth line to the SEM six times at each of 2 respective points spaced along the length of the fifth line; and a CD of a sixth line of the line and space pattern may be measured by integrating 12 image frames produced by exposing the sixth line to the SEM 12 times at only 1 point along the sixth line.

In an alternative technique shown in FIG. 10, several lines of a photosensitive film line and space pattern are exposed to the SEM the same number of times at each of the same number of points along the length of the line, and this process is carried out differently among at least two sets of the lines. This technique is useful, i.e., can ensure the accuracy of OPC modeling, if, for example, the photomask produces a pattern having one or more broken lines (or other types of features).

An example of the technique will now be described with reference to the figure.

First, a first line 300 is exposed to the SEM a first number of times (only one time in this example) at each of a first number of points (16 in this example) along the length of the first line 300. More specifically, a first image frame is obtained using the SEM at a first point 301 of the first line 300. Next, a second image frame is obtained using the SEM at a second point 302 spaced apart from the first point 301 by a predetermined distance a along a length of the first pattern 300. Third through sixteenth image frames are then obtained, respectively, at third through sixteenth points 303 . . . 316 in the same manner.

Next, values of signals representative of these sixteen image frames are integrated to form a SEM image of the first line 300, and a value of the CD of the first pattern 300 is extracted from the SEM image of the first line 300.

Subsequently, another first line 320 spaced apart from the first line 300 and intended to be identical (in terms of its CD) to that the line 300 is selected, and the CD of the (second) first line 320 is determined in the same manner as for the (first) first line 300.

Then, the CDs of the first lines 300 and 320 (lines of a first set) are averaged to obtain “a CD of a line whose points are exposed to the SEM each only one time”. Although in this example only two first lines 300 and 320 are used for each sequence in which each point along a line is exposed to the SEM only once, more than two first lines may be sampled in this way and their CDs averaged.

Next, second lines 340 and 360 (i.e., lines of a second set) spaced apart from the first lines 300 and 320 and identical to the first patterns 300 and 320 are selected from the line and space photosensitive film pattern.

Then, one of (a first of) the second lines 340 is exposed to the SEM at a second number of points (different from the first number) along the length thereof, and at each point a number of times different from the first number of times, e.g., two times. Then, the CD of the (first) second line 340 is determined.

In this example, first, first and second image frames are obtained by exposing the second line 340 to the SEM two times at a first point 341 thereon. Then, third and fourth image frames are obtained using the SEM by exposing the second line 340 to the SEM at a second point 342 spaced apart from the first point 341 by the predetermined distance a along the length direction of the second line 340. Next, fifth through sixteenth image frames are obtained using the SEM by exposing the second line 340 to the SEM two times at each of third through eighth points 343 . . . 348.

These sixteen image frames are integrated to form an SEM image of the second line 340, and the CD of the second line 340 is extracted from the SEM image.

Then, the (second) second line 360 spaced apart from the first second line 340 is selected, and the CD of the second line 360 is obtained in the same manner as for the second line 340.

Next, the “CD of a line whose points are each exposed to the SEM two times” is obtained by averaging the CDs of the second lines 340 and 360. Again, more than two second lines may be used to obtain an average value of the CD.

Then, a plurality of third lines (not shown) spaced apart from the second lines 340 and 360 are selected from the line and space photosensitive film pattern, and the same process as those described above for the first set of lines (300 and 320) and second set of lines (340 and 360) is performed. For example, each of the third lines is exposed to the SEM four times at each of four points spaced from one another by the predetermined distance a along the length thereof, and the “CD of a line whose points are each exposed to the SEM four times” is obtained. Likewise, each of the fourth lines (not shown) of the line and space pattern is exposed to the SEM eight times at each of two points spaced from one another by the predetermined distance a along the length thereof, and the “CD of a line whose points are each exposed to the SEM eight times” is obtained. Then each of the fifth lines (not shown) of the line and space pattern is exposed to the SEM sixteen times at each of only one point thereon, and the “CD of a line having a point exposed to the SEM sixteen times” is obtained.

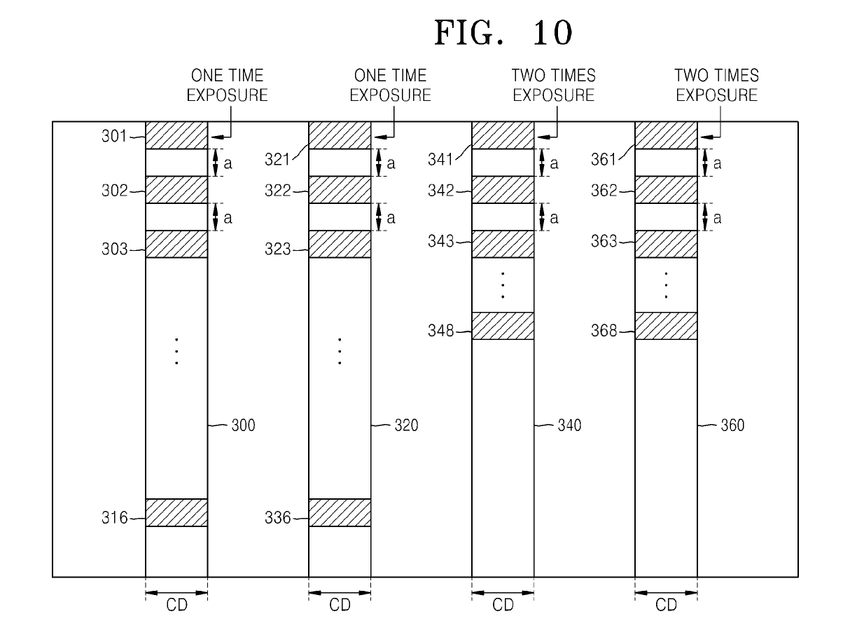

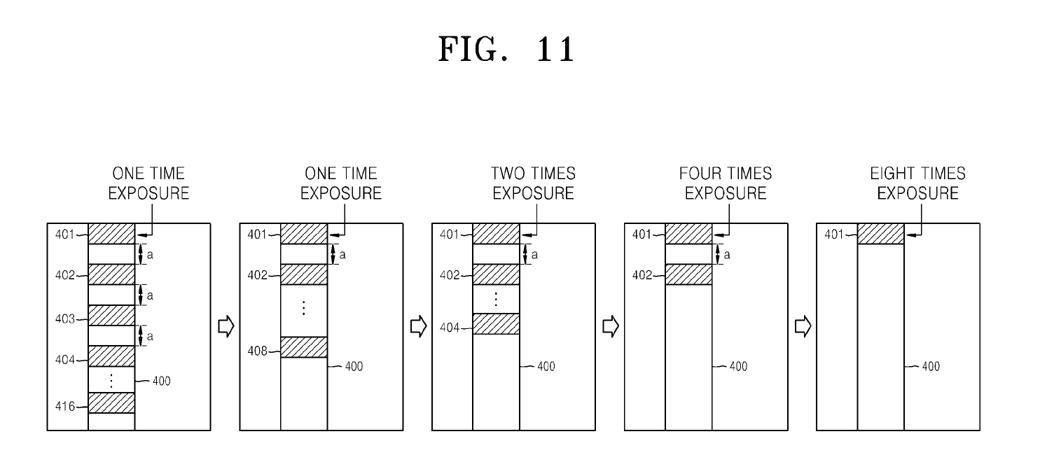

Still another technique of acquiring CD data using the photomask will be described with reference to FIG. 11. In this technique, only one feature of the photomask pattern is transcribed onto a substrate for use in generating the CD data.

More specifically, referring to FIG. 11, only one feature, i.e., a line 400, formed on a wafer using the photomask is selected.

Then, image frames of the line 400 are produced by exposing the line 400 to the SEM a first number of times, for example, one time, at each of a first number of points (401, 402, . . . 416 in this example) spaced from each other by a predetermined distance a along the length of the line 400. A SEM image is obtained by integrating the image frames (16 in this example). Then the CD of the line 400 is extracted (measured) from the SEM image.

Then, the first point 401 of the line 400, which has already been exposed to the SEM once, is selected, and the first point 401 is again exposed to the SEM a second number of times, for example, one time, to obtain a second image frame of the first point 401. In other words, several image frames—equal to “the first number of times+the second number of times”—of the first point 401 are produced.

Next, the second point 402 that has been exposed to the SEM once and is spaced apart from the first point 401 by the predetermined distance a along the length of the line 400 is selected, and a second image frame at the second point 402 is produced by exposing the second point 402 to the SEM one time. In the same way, second image frames of the third through eighth points 403 through 408, which have also already been exposed to the SEM one time, are obtained.

The first image frames of the first through eighth points 401 through 408 of the line 400, and the second image frames of the first through eighth points 401 through 408 are integrated to form a SEM image of the line 400, and the CD of the first line is extracted (measured) from the SEM image. That is, a “CD of the line 400 exposed to the SEM two times” is obtained.

Then, the first point 401 of the line 400 already exposed to the SEM two times is selected, and third and fourth image frames of the first point 401 are produced by exposing the first point 401 to the SEM a third number of times, for example, two times. Next, the second point 402 spaced apart from the first point 401 by the predetermined distance a along the length of the first pattern 400 and already exposed to the SEM two times is selected, and the second point 402 is exposed to the SEM two more times to produce third and fourth image frames of the second point 402. Third and fourth image frames of the third and fourth points 403 and 404 already exposed to the SEM two times are produced in the same manner. Then a SEM image of the line 400 exposed to the SEM four times is obtained by integrating the first and second image frames of the first through fourth points 401 through 404 of the first line 400 already exposed to the SEM two times, and the third and fourth image frames produced by further exposing the first through fourth points 401 through 404 to the SEM two times, and the CD of the line 400 is extracted (measured) from the SEM image.

Next, the first point 401 of the line 400 already exposed to the SEM four times is selected, and fifth through eighth image frames are produced by exposing the first point 401 to the SEM four more times. Then the second point 402 spaced from the first point 401 by the predetermined distance a along the length of the line 400 and already exposed to the SEM four times is selected, and fifth through eighth image frames are produced by exposing the second point 402 a fourth number of times, for example, four times. A SEM image of the line 400 is formed by integrating the first through fourth image frames of the first and second points 401 and 402 of the line 400 already exposed to the SEM four times, and the fifth through eighth image frames produced by further exposing the first and second points 401 and 402 to the SEM four times. The CD of the line 400 is extracted (measured) from the SEM image so obtained.

Next, the first point 401 of the first pattern 400 already exposed to the SEM eight times is selected, and ninth through sixteenth image frames are produced by exposing the first point 401 to the SEM a fifth number of times, for example, eight more times. A SEM image of the line 400 is produced by integrating the first through eighth image frames of the first point 401 of the first pattern 400 already exposed to the SEM eight times, and the ninth through sixteenth image frames produced by further exposing the first point 401 to the SEM eight more times. Then the CD of the line 400 is extracted (measured) from this SEM image.

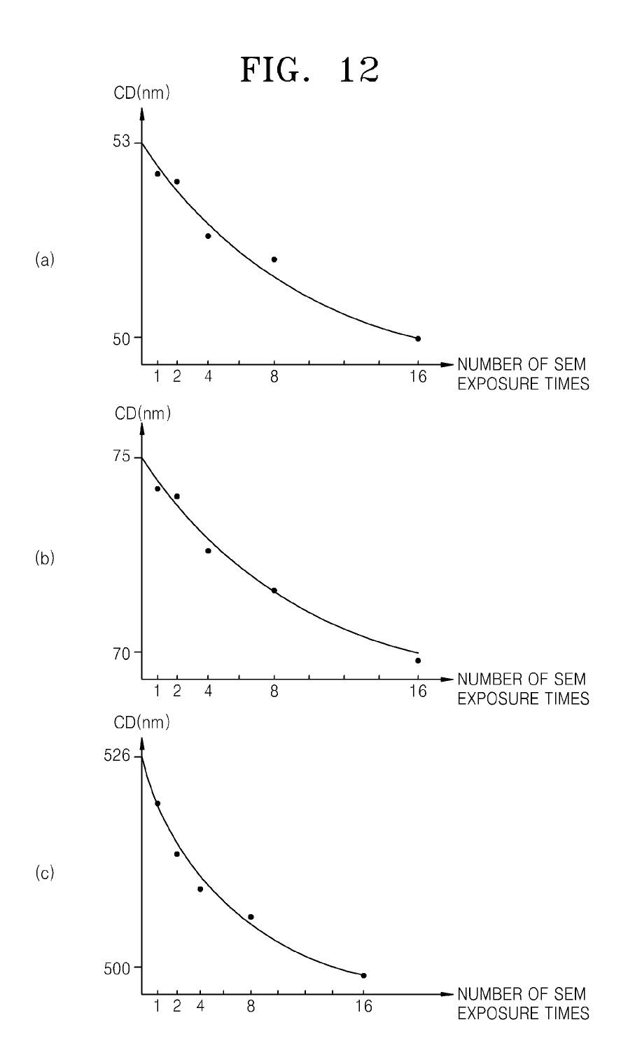

Methods of approximating the value of the CD of a line and space pattern produced by the photomask, at a point in time before the pattern has been shrunk by the SEM, will be described with reference to FIGS. 12A through 12C. As mentioned above, these methods use the CD data of the line and space pattern acquired only using a SEM (according to any of the techniques described above with reference to FIGS. 9 through 11).

FIG. 12A is a graph when the CD of the line and space pattern to be produced using the photomask is designed to be 50 nm, FIG. 12B is a graph when the CD of the line and space pattern is designed to be 70 nm, and FIG. 12C is a graph when the CD of the line and space pattern is designed to be 500 nm. In each of these graphs, the plots connect the values of CDs extracted (measured) from the SEM images obtained by integrating the image frames produced by exposing a line or lines different numbers of times (SEM exposure times in the graphs). The value of the CD when the number of SEM exposure times is 0 is obtained by extrapolation.

That is, in each of the graphs of FIGS. 12A through 12C, the graph is drawn using measured CDs of a pattern produced using the photomask, and the values of which are acquired using only a SEM according to a technique of exposing a point or points along one or more lines of the pattern to the SEM. The resulting plot is then extrapolated to find the value of the CD of the line and space pattern corresponding to the number 0 of SEM exposure times, i.e., a pseudo CD_{AFM}.

In each of the graphs of FIGS. 12A through 12C, the plot is formed as a curve, i.e., expresses at least a quadratic function, but alternatively, the plot may be linear (i.e., may express a linear function) and the pseudo CD_{AFM}, may be predicted by extrapolating the linear function.

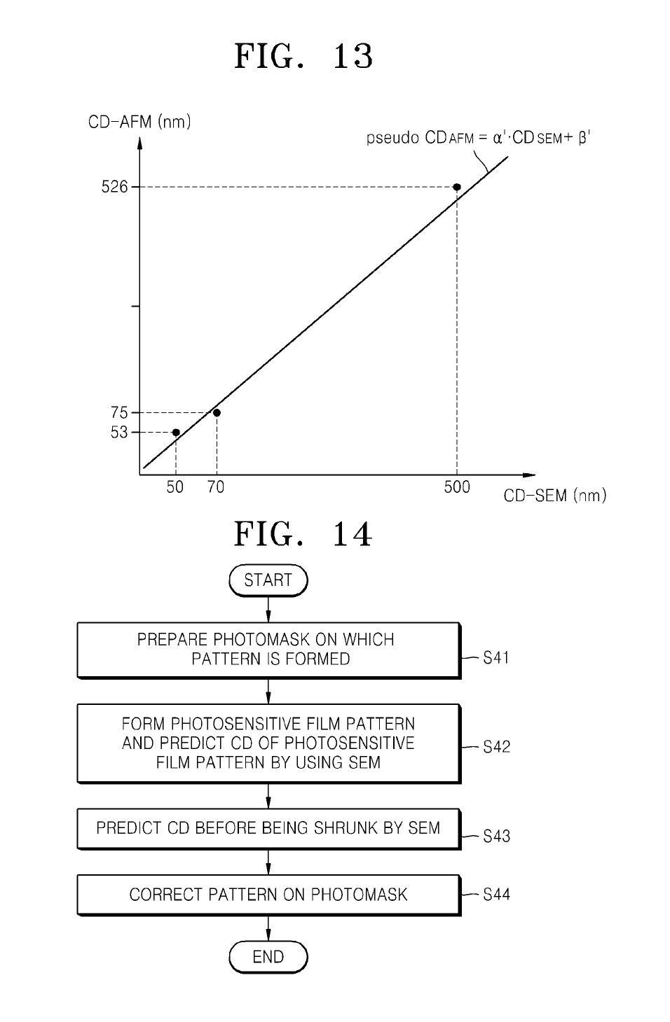

FIG. 13 is a graph illustrating a SEM bias model created using data from the graphs of FIGS. 12A through 12C.

In this example, the data used is that of CD-SEM images of photosensitive film patterns produced using a photomask and each of which images is formed by integrating 16 image frames of a feature/features which make up a photosensitive film pattern. The SEM bias model of the photomask in this example is a linear function expressed as pseudo CD_{AFM}=α′·CDₛₑₘ+β′ wherein pseudo CD_{AFM} denotes the CD of the photosensitive film pattern at a point in time before the CD has begun to shrink due to its being irradiated by the electron beam of the SEM, α′ denotes a slope of the function, and β′ denotes the y-intercept (offset) of the function, and CDₛₑₘ denotes the CD of the photosensitive film pattern measured using the SEM.

In this bias model, therefore, α′ is obtained from data points in the graphs of FIGS. 12A through 12C, and β′ using regression analysis or extrapolation.

The SEM bias model can thus be used to predict the CD of the photosensitive film pattern at a point in time before the CD begins to shrink under the effects of the SEM. Moreover, an effect of the SEM on the pitch of the photosensitive film pattern, the slope of the sidewalls of the photosensitive film pattern may be incorporated into the SEM bias model. In other words, the bias model of the photomask may be represented as a function that also takes into account changes in the slope, pitch, etc. of the photosensitive film pattern, and which function may be expressed as:

CD_{before shrinkage}=f(CDₛₑₘ(bar size), pitch, etc.)

Conventionally, OPC modeling is performed based on a function of CD=CDₛₑₘ+offset, but more accurate OPC modeling is possible according to the inventive concept by considering changes due to use of the SEM, i.e., changes in the CD or pitch due to the SEM. Thus, when the pattern of the photomask is corrected by OPC based on the SEM bias model created according to the inventive concept, the photomask can produce a more uniform minute pattern.

Also, by taking into account inherent characteristics of the SEM operations, a root mean square (RMS) value of a residual CD error may be reduced.

The techniques of approximating the value of the CD of the film pattern, at a point in time before the film pattern, such as a line and space pattern, is shrunk by the SEM and obtaining the SEM bias model have been described for use in cases in the photosensitive film pattern shrinks given amounts according to the number of times the film pattern is exposed to the SEM.

However, if the photosensitive film pattern is aperiodic or not continuous, it is difficult to measure the CD of the photosensitive film pattern by exposing the film pattern to the SEM a number of times and integrating the results. However, the SEM bias model can be used to discern parameters of the SEM operation via regression analysis.

For example, assuming that the photosensitive film pattern is dependent on the value of CD and the SEM bias model is pseudo CD_{AFM}=α′·CDₛₑₘ+β′, the SEM bias model and in particular, parameters of α′ and β′, can be obtained for a particular SEM operation and factored into the OPC.

Finally, a method of fabricating a photomask, according to the inventive concept, will now be summarized with reference to the flowchart of FIG. 14.

Referring to FIG. 14, the method includes providing a photomask having a photomask pattern (S41) which step may entail forming the photomask pattern at a surface of a mask substrate, forming a photosensitive film pattern on a substrate, e.g., on a wafer, by using the photomask in a lithographic process and measuring a CD of the photosensitive film pattern by using a SEM (S42), approximating (predicting) what the CD of the photosensitive film pattern was at a point in time before the SEM was used, i.e., before the CD may have begun to shrink upon being irradiated by the electron beam of the SEM (S43), and correcting a mask pattern of a photomask and thereby transforming the photomask by performing OPC based at least in part on the CD approximated (predicted) in S43 (S44). Various techniques used for approximating (predicting) the CD of the photosensitive film pattern (S43) have been described above and therefore, will not be described or summarized here for the sake of brevity. Also, this process S43 may be performed on the photomask used to form the film pattern, i.e., as a process in the course of manufacturing the photomask, or on a similar photomask mass produced along with that used to form the film pattern, for example.

Accordingly, a photomask having a more elaborate pattern, capable of producing a more uniform film pattern, for example, may be provided.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A method of fabricating a photomask, the method comprising:
providing a photomask having a mask pattern;
patterning a film on a substrate using the photomask in a lithographic process to thereby form a film pattern bearing an image of at least part of the mask pattern;
measuring a critical dimension (CD) of the film pattern, wherein the measuring includes imaging the film pattern using a scanning electron microscope (SEM) and extracting a value of the CD from an image of the film pattern produced by the SEM;
based on the measured CD, approximating the value of the CD of the film pattern possessed by the film pattern at a point in time before the film pattern was imaged by the SEM; and
performing an optical proximity effect correction (OPC) of the photomask using the approximated value of the CD, thereby altering an original mask pattern of the photomask subjected to the OPC.

2. The method of claim 1, wherein the providing of the photomask comprises forming only a single feature or a plurality of features, as the basic version of the mask pattern, at a surface of a mask substrate.

3. The method of claim 1, wherein the measuring of the CD of the film pattern further comprises measuring the CD of the film pattern using an atomic force microscope (AFM) before the film pattern is imaged by the SEM, and
the approximating of the value of the CD of the film pattern comprises developing a metrology model based on the values of the CD obtained using the AFM and the SEM, respectively.

4. The method of claim 1, wherein the measuring of the CD comprises exposing the film pattern a number of times to the SEM to produce multiple image frames of the film pattern.

5. The method of claim 4, wherein the film pattern has a plurality of similarly shaped elongated features spaced apart from each other across a surface of the substrate, and
the measuring of the CD comprises:
selecting a first feature of the film pattern formed using the photomask, and producing first image frames by exposing the first feature to the SEM a first number of times at each of a first number of points along the length of the first feature;
determining a CD of the first feature using the first image frames;
selecting a second feature of the film pattern formed using the photomask, and producing second image frames by exposing the second feature to the SEM a second number of times, different from the first number of times, at each of a second number of points, different from the first number of points, along the length of the second feature; and
determining a CD of the second feature using the second image frames.

6. The method of claim 5, wherein the approximating of the value of the CD of the film pattern comprises extrapolating data which comprises the values of the CDs of the first and second features of the film pattern.

7. The method of claim 4, wherein the film pattern has a plurality of similarly shaped elongated features spaced apart from each other across a surface of the substrate, and the measuring of the CD of the film pattern comprises:
selecting a plurality of first features of the film pattern formed using the photomask, and producing first image frames of each of the first features by exposing each of the first features to the SEM a first number of times at each of a first number of points along the length of the first feature;
determining a CD of each of the first features using the first image frames produced thereof, and averaging the CDs of each of the first features to obtain an average first CD;
selecting a plurality of second features of the film pattern formed using the photomask, and producing second image frames of each of the second features by exposing each of the second features to the SEM a second number of times, different from the first number of times, at each of a second number of points, different from the first number of points, along the length of the second feature; and
determining a CD of each of the second features using the second image frames produced thereof, and averaging the CDs of each of the second features to obtain an average second CD.

8. The method of claim 7, wherein the approximating of the value of the CD of the film pattern comprises extrapolating data which comprises the values of the average CDs of the first features and second features of the film pattern.

9. The method of claim 4, wherein the film pattern has an elongated feature on the substrate, and the measuring of the CD of the film pattern comprises:
producing a first set of a first number of image frames of the feature of the film pattern by exposing the feature to the SEM a number of times at each of a first number of points along the length of the feature;
determining a CD of the feature of the film pattern using the first set of image frames;
producing a second set of a second number of image frames, different from the first number of image frames, of the feature of the film pattern by exposing the feature to the SEM a number of times at each of a second number of points, different than the first number of points, along the length of the feature; and
determining a CD of the feature of the film pattern using an accumulation of the image frames of the first and second sets.

10. The method of claim 9, wherein the approximating of the value of the CD of the film pattern comprises extrapolating data which comprises the determined CDs of the feature of the film pattern.

11. The method of claim 1, further comprising:
creating a SEM bias model by carrying out the patterning, measuring and approximating steps several different times, wherein the patterning is carried out to produce respective film patterns having significantly different CDs, and
wherein the optical proximity effect correction factors in a value obtained from the SEM bias model.

12. A method of fabricating a photomask, the method comprising:
providing a photomask having a mask pattern;
patterning a film on a substrate using the photomask in a lithographic process to thereby form a film pattern bearing an image of at least one feature of the mask pattern;
determining at least one value of the critical dimension (CD) of the film by scanning the film pattern with an electron beam of a scanning electron microscope (SEM);
based at least in part on the at least one value of the CD determined using the SEM, approximating the value of the CD of the film pattern possessed by the film pattern at a point in time before the film pattern was irradiated by the electron beam of the SEM, whereby the approximated value of the CD of the film pattern is not influenced by any shrinkage of the film pattern caused by the electron beam;
factoring the approximated value of the CD of the film pattern into an optical proximity effect correction (OPC) model; and
altering a photomask, by changing a mask pattern thereof, based on the optical proximity effect correction (OPC) model into which the approximated value of the CD of the film pattern has been factored.

13. The method of claim 12, further comprising measuring the CD of the film pattern with a probe, and
wherein the approximating of the value of the CD of the film pattern comprises developing a metrology model based on the value of the CD measured using the probe, and on the at least one value of the CD determined using the SEM.

14. The method of claim 1, wherein the scanning of the film pattern comprises irradiating the film pattern in a plurality of respective sequences with the electron beam of the SEM to produce sets of image frames of the film pattern, and the determining of at least one value of the CD of the film pattern comprises extracting values of the CD of the film pattern from the sets of image frames, respectively.

15. The method of claim 14, wherein the film pattern has a plurality of similarly shaped elongated features spaced apart from each other across a surface of the substrate;
the scanning of the film pattern and the extracting of the values of the CD comprise:
selecting a first feature of the film pattern formed using the photomask, and producing first image frames by exposing the first feature to the SEM a first number of times at each of a first number of points along the length of the first feature,
determining a value of the CD of the first feature using the first image frames,
selecting a second feature of the film pattern formed using the photomask, and producing second image frames by exposing the second feature to the SEM a second number of times, different from the first number of times, at each of a second number of points, different from the first number of points, along the length of the second feature, and
determining a value of the CD of the second feature using the second image frames; and
the approximating of the value of the CD of the film pattern comprises extrapolating data which comprises the values of the CDs of the first and second features of the film pattern.

16. The method of claim 14, wherein the film pattern has a plurality of similarly shaped elongated features spaced apart from each other across a surface of the substrate;
the scanning of the film pattern and the extracting of the values of the CD comprise:
selecting a plurality of first features of the film pattern formed using the photomask, and producing first image frames of each of the first features by exposing each of the first features to the SEM a first number of times at each of a first number of points along the length of the first feature,
determining a value of the CD of each of the first features using the first image frames produced thereof, and averaging the values of the CDs of each of the first features to obtain an average first CD value,
selecting a plurality of second features of the film pattern formed using the photomask, and producing second image frames of each of the second features by exposing each of the second features to the SEM a second number of times, different from the first number of times, at each of a second number of points, different from the first number of points, along the length of the second feature, and
determining a value of the CD of each of the second features using the second image frames produced thereof, and averaging the values of the CDs of each of the second features to obtain an average second CD value; and
the approximating of the value of the CD of the film pattern comprises extrapolating data which comprises the average CD values.

17. The method of claim 14, wherein the film pattern has an elongated feature on the substrate;
the scanning of the film pattern and the extracting of the values of the CD comprise:
producing a first set of a first number of image frames of the feature of the film pattern by exposing the feature to the SEM a number of times at each of a first number of points along the length of the feature,
determining a CD of the feature of the film pattern using the first set of image frames;
producing a second set of a second number of image frames, different from the first number of image frames, of the feature of the film pattern by exposing the feature to the SEM a number of times at each of a second number of points, different than the first number of points, along the length of the feature, and
determining a CD of the feature of the film pattern using an accumulation of the image frames of the first and second sets; and
the approximating of the value of the CD of the film pattern comprises extrapolating data which comprises the determined CDs of the feature of the film pattern.

18. The method of claim 12, further comprising:
creating a SEM bias model by carrying out the patterning, measuring and approximating steps several different times, wherein the patterning is carried out to produce respective film patterns having significantly different CDs, and
wherein the factoring of the approximated value of the CD of the film pattern into the OPC model comprises factoring a value from the SEM bias model into the OPC model.

19. A method for use in fabricating a photomask, the method comprising:
providing a photomask having a mask pattern;
forming a photosensitive film pattern using the photomask and measuring a CD of the photosensitive film pattern at least one time using a scanning electron microscope (SEM); and
predicting a value of the CD of the photosensitive film pattern, at a point in time before the CD of the film pattern has been altered by the SEM, using at least a value or values of the CD measured using the SEM.
